(19) United States
(12) Patent Application Publication
(10) Pub. No.: US 2026/0282388 A1
(43) Pub. Date: Sep. 17, 2026

(54) MAGNETIC MEMORY DEVICE

(71) Applicant: Kioxia Corporation, Tokyo (JP)

(72) Inventors: Kazuya SAWADA, Seoul (KR); Tadaaki OIKAWA, Seoul (KR); Soichi OIKAWA, Hachioji Tokyo (JP); Kenji FUKUDA, Seoul (KR)

(73) Assignee: Kioxia Corporation, Tokyo (JP)

(21) Appl. No.: 19/325,814

(22) Filed: Sep. 11, 2025

(30) Foreign Application Priority Data
Mar. 17, 2025 (JP) 2025-042876

(51) Int. Cl. H10B 61/00; H10N 50/10; H10N 50/85

(52) U.S. Cl. CPC H10B 61/10; H10N 50/10; H10N 50/85

(57) ABSTRACT

According to one embodiment, a magnetic memory device includes: a first ferromagnetic layer; a second ferromagnetic layer; a third ferromagnetic layer; a first nonmagnetic layer disposed between the first ferromagnetic layer and the second ferromagnetic layer; and a second nonmagnetic layer disposed between the second ferromagnetic layer and the third ferromagnetic layer. The second ferromagnetic layer includes a third nonmagnetic layer containing platinum (Pt), a fourth ferromagnetic layer containing cobalt (Co), and disposed on a side of the second nonmagnetic layer with respect to the third nonmagnetic layer, and the third nonmagnetic layer has a film thickness of less than or equal to 0.3 nm.

### CROSS-REFERENCE TO RELATED APPLICATION

This application is based upon and claims the benefit of priority from Japanese Patent Application No. 2025-042876, filed Mar. 17, 2025, the entire contents of which are incorporated herein by reference.

### FIELD

Embodiments described herein relate generally to a magnetic memory device.

### BACKGROUND

A magnetic memory device using a magnetoresistance element as a storage element is known. The magnetoresistance element is connected in series to a switching element and functions as a memory cell.

### BRIEF DESCRIPTION OF THE DRAWINGS

FIG. 1 is a block diagram illustrating an example of a configuration of a magnetic memory device according to an embodiment.

FIG. 2 is a circuit diagram illustrating an example of a circuit configuration of a memory cell array according to the embodiment.

FIG. 3 is a cross-sectional view illustrating an example of a cross-sectional structure of the memory cell array according to the embodiment.

FIG. 4 is a cross-sectional view illustrating an example of a cross-sectional structure of the memory cell array according to the embodiment.

FIG. 5 is a cross-sectional view illustrating an example of a cross-sectional structure of a magnetoresistance element according to the embodiment.

FIG. 6 is a cross-sectional view illustrating an example of a cross-sectional structure of a reference layer included in the magnetoresistance element according to the embodiment.

FIG. 7 is a cross-sectional view illustrating an example of a cross-sectional structure of a reference layer included in a magnetoresistance element according to a first modification.

FIG. 8 is a cross-sectional view illustrating an example of a cross-sectional structure of a reference layer included in a magnetoresistance element according to a second modification.

FIG. 9 is a cross-sectional view illustrating an example of a cross-sectional structure of a reference layer included in a magnetoresistance element according to a third modification.

FIG. 10 is a cross-sectional view illustrating an example of a cross-sectional structure of a magnetoresistance element according to a fourth modification.

### DETAILED DESCRIPTION

In general, according to one embodiment, a magnetic memory device includes: a first ferromagnetic layer; a second ferromagnetic layer; a third ferromagnetic layer; a first nonmagnetic layer disposed between the first ferromagnetic layer and the second ferromagnetic layer; and a second nonmagnetic layer disposed between the second ferromagnetic layer and the third ferromagnetic layer. The second ferromagnetic layer includes a third nonmagnetic layer containing platinum (Pt), a fourth ferromagnetic layer containing cobalt (Co), and disposed on a side of the second nonmagnetic layer with respect to the third nonmagnetic layer, and the third nonmagnetic layer has a film thickness of less than or equal to 0.3 nm.

Hereinafter, embodiments will be described with reference to the drawings. In the description, components having substantially the same functions and configurations are denoted by the same reference signs. In addition, the following embodiment illustrates technical ideas. The embodiment does not specify the materials, shapes, structures, arrangement, and the like of components. Various modifications can be made to the embodiment.

In the present specification, a magnetic memory device is, for example, a magnetoresistance random access memory (MRAM). The magnetic memory device includes a magnetoresistance element as a storage element. The magnetoresistance element is a variable resistance element having a magnetoresistance effect by a magnetic tunnel junction (MTJ). The magnetoresistance element is also referred to as an MTJ element.

In addition, in the present specification, an “A/B multilayer film” indicates a stacked structure of a film containing an element A and a film containing an element B.

### 1. EMBODIMENT

An embodiment will be described.

### 1.1. Configuration

First, a configuration of a magnetic memory device according to an embodiment will be described.

### 1.1.1. Magnetic Memory Device

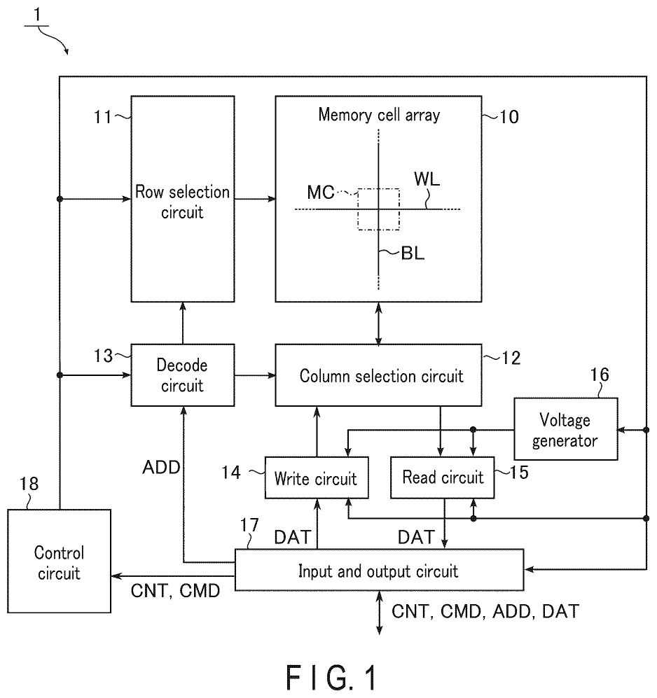

FIG. 1 is a block diagram illustrating an example of the configuration of the magnetic memory device according to the embodiment. The magnetic memory device 1 includes a memory cell array 10, a row selection circuit 11, a column selection circuit 12, a decode circuit 13, a write circuit 14, a read circuit 15, a voltage generator 16, an input and output circuit 17, and a control circuit 18.

The memory cell array 10 is a data storage unit in the magnetic memory device 1. The memory cell array 10 includes a plurality of memory cells MC. Each of the plurality of memory cells MC is associated with a set of a row and a column. Memory cells MC in the same row are connected to the same word line WL. Memory cells MC in the same column are connected to the same bit line BL.

The row selection circuit 11 is a circuit that selects a row of the memory cell array 10. The row selection circuit 11 is connected to the memory cell array 10 via word lines WL. A result (row address) of decoding an address ADD from the decode circuit 13 is supplied to the row selection circuit 11. The row selection circuit 11 selects a word line WL corresponding to the row based on the result of decoding the address ADD. Hereinafter, the selected word line WL is referred to as a selected word line WL. The word lines WL other than the selected word line WL are referred to as unselected word lines WL.

The column selection circuit 12 is a circuit that selects a column of the memory cell array 10. The column selection circuit 12 is connected to the memory cell array 10 via bit lines BL. A result (column address) of decoding the address ADD from the decode circuit 13 is supplied to the column selection circuit 12. The column selection circuit 12 selects a bit line BL corresponding to the column based on the result of decoding the address ADD. Hereinafter, the selected bit line BL is referred to as a selected bit line BL. The bit lines BL other than the selected bit line BL are referred to as unselected bit lines BL.

The decode circuit 13 is a decoder that decodes the address ADD from the input and output circuit 17. The decode circuit 13 supplies the results of decoding the address ADD to the row selection circuit 11 and the column selection circuit 12. The address ADD includes the column address and the row address.

The write circuit 14 includes, for example, a write driver (not illustrated). The write circuit 14 writes data to the memory cells MC.

The read circuit 15 includes, for example, a sense amplifier (not illustrated). The read circuit 15 reads data from the memory cells MC.

The voltage generator 16 generates voltages for various operations of the memory cell array 10 using a power supply voltage provided from the outside (not illustrated) of the magnetic memory device 1. For example, the voltage generator 16 generates various voltages necessary for the write operation and outputs the voltages to the write circuit 14. Furthermore, for example, the voltage generator 16 generates various voltages required for the read operation and outputs the voltages to the read circuit 15.

The input and output circuit 17 manages communication with the outside of the magnetic memory device 1. The input and output circuit 17 transfers the address ADD from the outside of the magnetic memory device 1 to the decode circuit 13. The input and output circuit 17 transfers a command CMD from the outside of the magnetic memory device 1 to the control circuit 18. The input and output circuit 17 transmits and receives various control signals CNT to and from the outside of the magnetic memory device 1 and the control circuit 18. The input and output circuit 17 transfers data DAT from the outside of the magnetic memory device 1 to the write circuit 14, and outputs the data DAT transferred from the read circuit 15 to the outside of the magnetic memory device 1.

The control circuit 18 includes, for example, a processor such as a central processing unit (CPU), a read only memory (ROM), and a random access memory (RAM). The control circuit 18 controls operations of the row selection circuit 11, the column selection circuit 12, the decode circuit 13, the write circuit 14, the read circuit 15, the voltage generator 16, and the input and output circuit 17 in the magnetic memory device 1 based on the control signals CNT and the command CMD.

### 1.1.2. Circuit Configuration of Memory Cell Array

Next, a circuit configuration of the memory cell array of the magnetic memory device according to the embodiment will be described.

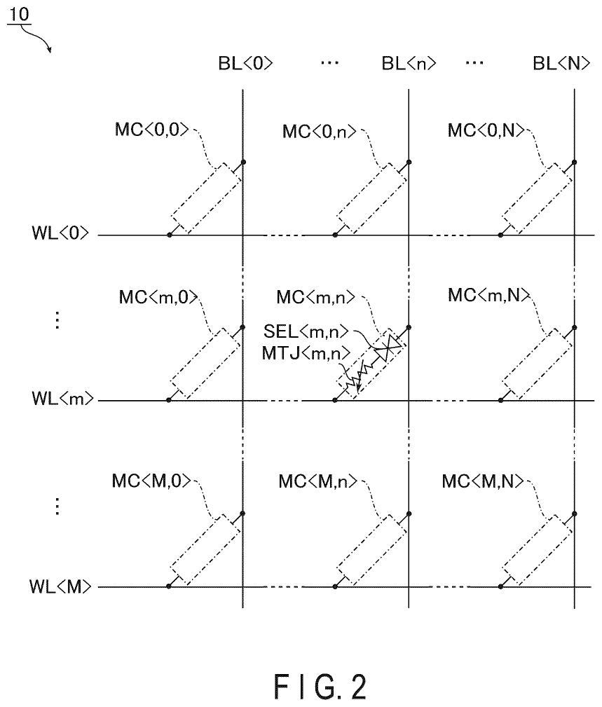

FIG. 2 is a circuit diagram illustrating an example of the circuit configuration of the memory cell array according to the embodiment. In FIG. 2, each of the word lines WL and the bit lines BL is classified and illustrated by a subscript including an index (“<>”).

The memory cell array 10 includes the plurality of memory cells MC, the plurality of word lines WL, and the plurality of bit lines BL. In the example illustrated in FIG. 2, the plurality of memory cells MC includes (M+1)×(N+1) memory cells MC<0, 0>, . . . , MC<0, n>, . . . , MC<0, N>, . . . , MC<m, 0>, . . . , MC<m, n>, . . . MC<m, N>, . . . , MC<M, 0>, . . . , MC<M, n>, . . . , and MC<M, N> (M and N are integers greater than or equal to 1, 0 ≤m≤M, and 0 ≤n≤N). In the example illustrated in FIG. 2, a case where M and N are integers greater than or equal to 1 has been described, but the present disclosure is not limited thereto. M and N may be 0. The plurality of word lines WL include (M+1) word lines WL<0>, . . . , WL<m>, . . . , and WL<M>. The plurality of bit lines BL include (N+1) bit lines BL<0>, . . . , BL<n>, . . . , and BL<N>.

The plurality of memory cells MC are arranged in a matrix in the memory cell array 10. Each of the memory cells MC is associated with a respective one of the plurality of word lines WL and a respective one of the plurality of bit lines BL. That is, the memory cell MC<m, n> is connected between the word line WL<m> and the bit line BL<n>.

The memory cell MC<m, n> is a two-terminal memory cell having a first end connected to the word line WL<m> and a second end connected to the bit line BL<n>. The memory cell MC<m, n> includes a switching element SEL<m, n> and a magnetoresistance element MTJ<m, n>.

The switching element SEL is a two-terminal switching element including two terminals. The two-terminal switching element is different from a three-terminal switching element such as a transistor in that the two-terminal switching element does not include a third terminal. In a case where a voltage applied between the two terminals is less than a threshold voltage Vth, the switching element SEL is in a “high resistance” state or an “OFF” state, for example, an electrically non-conductive state. In a case where a voltage applied between the two terminals is higher than or equal to the threshold voltage Vth, the switching element SEL is in a “low resistance” state or an “ON” state, for example, an electrically conductive state. More specifically, for example, when a voltage that is lower than the threshold voltage Vth is applied to the corresponding memory cell MC, the switching element SEL interrupts a current (enters the OFF state) as an insulator having a large resistance value. When a voltage that is higher than or equal to the threshold voltage Vth is applied to the corresponding memory cell MC, the switching element SEL causes the current to flow as a conductor having a small resistance value (enters the ON state). The switching element SEL switches whether to cause the current to flow or interrupt the current based on the magnitude of the voltage applied to the corresponding memory cell MC regardless of the polarity of the voltage applied between the two terminals (regardless of a direction in which the current flows).

The magnetoresistance element MTJ is a variable resistance element. The magnetoresistance element MTJ can switch a resistance value between the low resistance state and the high resistance state based on the current for which a path is controlled by the switching element SEL. The magnetoresistance element MTJ functions as a storage element that stores data in a nonvolatile manner based on a change in the resistance state of the magnetoresistance element MTJ.

### 1.1.3. Cross-Sectional Structures of Memory Cell Array

Next, cross-sectional structures of the memory cell array according to the embodiment will be described.

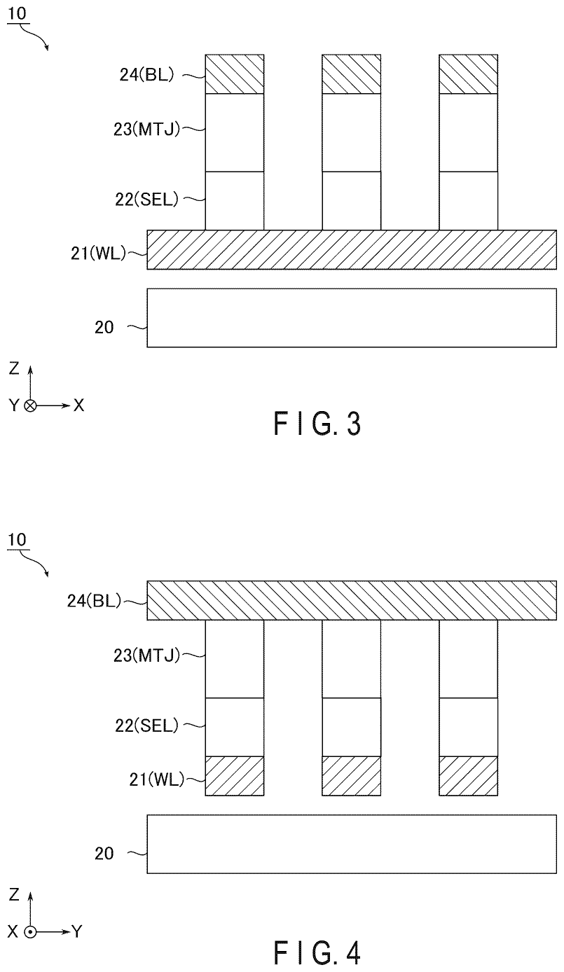

FIGS. 3 and 4 are cross-sectional views illustrating an example of the cross-sectional structures of the memory cell array according to the embodiment. As illustrated in FIGS. 3 and 4, the memory cell array 10 is disposed above a substrate 20. Note that a plane along the cross-sectional view illustrated in FIG. 3 and a plane along the cross-sectional view illustrated in FIG. 4 intersect a surface of the substrate 20 and intersect each other.

In the following description, a plane parallel to the surface of the substrate 20 is an XY plane. Directions intersecting each other in the XY plane are defined as an X direction and a Y direction. A direction intersecting the XY plane is defined as a Z direction. In particular, a direction from the substrate 20 toward the memory cell array 10 is also referred to as an upward direction. A direction from the memory cell array 10 toward the substrate 20 is also referred to as a downward direction.

The memory cell array 10 includes a plurality of conductive layers 21, a plurality of element layers 22, a plurality of element layers 23, and a plurality of conductive layers 24.

Peripheral circuits such as the row selection circuit 11 and the column selection circuit 12 may be disposed between the substrate 20 and the memory cell array 10. No peripheral circuit may be disposed between the substrate 20 and the memory cell array 10. In a case where no peripheral circuit is disposed between the substrate 20 and the memory cell array 10, shallow trench isolation (STI) may be disposed in a portion of the substrate 20 located below the memory cell array 10.

The plurality of conductive layers 21 are disposed above the substrate 20. Each of the plurality of conductive layers 21 extends in the X direction. The plurality of conductive layers 21 are arranged in the Y direction. Each of the plurality of conductive layers 21 is used as a word line WL.

The plurality of element layers 22 are disposed on an upper surface of each of the plurality of conductive layers 21. The plurality of element layers 22 disposed on the upper surface of the same conductive layer 21 are arranged in the X direction. Each of the plurality of element layers 22 is used as a switching element SEL.

On an upper surface of each of the plurality of element layers 23, one corresponding element layer 22 is disposed. Each of the plurality of element layers 23 is used as a magnetoresistance element MTJ. Each of the element layers 23 has, for example, a circular shape as viewed in the Z direction. Each of the element layers 23 preferably has a diameter of less than or equal to 25 nanometers (nm). In one example, the diameter of each of the element layers 23 may be designed to be less than or equal to 20 nm.

One conductive layer 24 extending in the Y direction is disposed so as to be in contact with the upper surface of each of the plurality of element layers 23 arranged in the Y direction. The plurality of conductive layers 24 are arranged in the X direction. Each of the plurality of conductive layers 24 is used as a bit line BL.

### 1.1.4. Structure of Magnetoresistance Element

Next, a structure of the magnetoresistance element according to the embodiment will be described.

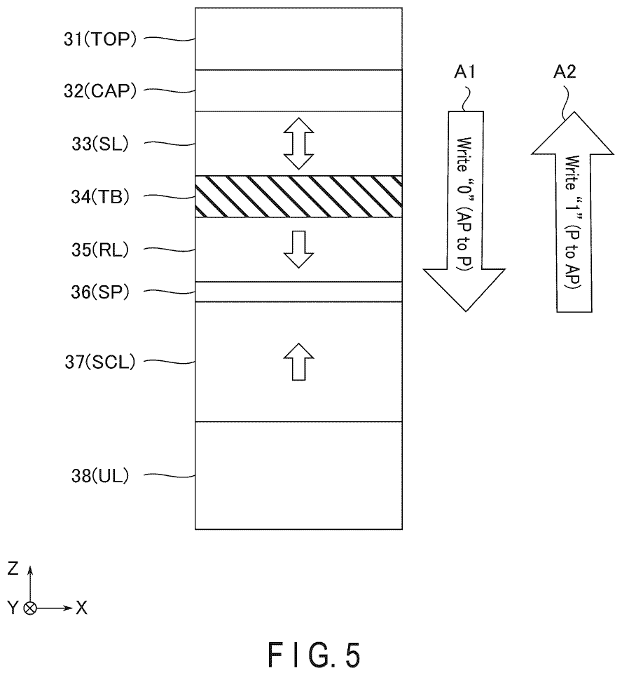

FIG. 5 is a cross-sectional view illustrating an example of a cross-sectional structure of the magnetoresistance element according to the embodiment. FIG. 5 illustrates, for example, an example of a cross section of the magnetoresistance element MTJ illustrated in FIGS. 3 and 4, taken along a plane (for example, the XZ plane) perpendicular to the Z axis.

As illustrated in FIG. 5, the magnetoresistance element MTJ includes, for example, a nonmagnet 31, a nonmagnet 32, a ferromagnet 33, a nonmagnet 34, a ferromagnet 35, a nonmagnet 36, a ferromagnet 37, and a nonmagnet 38.

For example, in the magnetoresistance element MTJ, a plurality of films are stacked in the order of the nonmagnet 38, the ferromagnet 37, the nonmagnet 36, the ferromagnet 35, the nonmagnet 34, the ferromagnet 33, the nonmagnet 32, and the nonmagnet 31 from the word line WL side toward the bit line BL side (in the Z direction). For example, the magnetoresistance element MTJ functions as a perpendicular magnetization type MTJ element in which a magnetization direction of a magnetic body constituting the magnetoresistance element MTJ is orthogonal to surfaces of the films. Note that the magnetoresistance element MTJ may include additional layers (not illustrated) between the above-described layers.

The nonmagnet 31 is a nonmagnetic conductor used as a top layer TOP. The nonmagnet 31 has a function as a top electrode that improves electrical connectivity between the upper end of the magnetoresistance element MTJ and the bit line BL or the word line WL. The nonmagnet 31 contains, for example, at least one element or compound selected from tungsten (W), tantalum (Ta), tantalum nitride (TaN), titanium (Ti), and titanium nitride (TiN).

The nonmagnet 32 is a nonmagnet used as a capping layer CAP. The nonmagnet 32 has a function of suppressing an increase in a damping constant of the ferromagnet 33 and reducing a write current. The nonmagnet 32 contains, for example, magnesium oxide (MgO), aluminum oxide (Al₂O₃), or rare earth oxide. The nonmagnet 32 may be a mixture of these oxides. That is, the nonmagnet 32 is not limited to a binary compound including two types of elements, and may contain a ternary compound including three types of elements, for example, magnesium aluminum oxide (MgAl₂O₄) or the like.

The ferromagnet 33 is used as a storage layer (SL). The ferromagnet 33 has an axis of easy magnetization in a direction perpendicular to the film surface of the ferromagnet 33. The magnetization direction of the ferromagnet 33 may be toward either the bit line BL side or the word line WL side along the Z axis. The ferromagnet 33 contains at least one element selected from iron (Fe), cobalt (Co), and nickel (Ni), and the ferromagnet 33 further contains boron (B). More specifically, for example, the ferromagnet 33 contains iron cobalt boron (FeCoB) or iron boride (FeB). The ferromagnet 33 may have a body-centered cubic (bcc) crystal structure.

The nonmagnet 34 is a nonmagnetic insulator used as a tunnel barrier layer (TB). The nonmagnet 34 functions as a seed material serving as nucleation of a crystalline film from an interface with the ferromagnet 33 in the crystallization of the ferromagnet 33. The nonmagnet 34 contains, for example, magnesium oxide (MgO). The nonmagnet 34 has a NaCl crystal structure in which the film surface is oriented in a (001) plane. The nonmagnet 34 is disposed between the ferromagnet 33 and the ferromagnet 35, and forms a magnetic tunnel junction together with the two ferromagnets 33 and 35.

The ferromagnet 35 is used as a reference layer (RL). The ferromagnet 35 has an axis of easy magnetization in a direction perpendicular to the film surface of the ferromagnet 35. The magnetization direction of the ferromagnet 35 may be toward either the bit line BL side or the word line WL side along the Z axis. The magnetization direction of the ferromagnet 35 is fixed and oriented toward the ferromagnet 37 in the example illustrated in FIG. 5. Note that “the magnetization direction is fixed” means that the magnetization direction does not change due to a current (spin torque) of a magnitude that can reverse the magnetization direction of the ferromagnet 33.

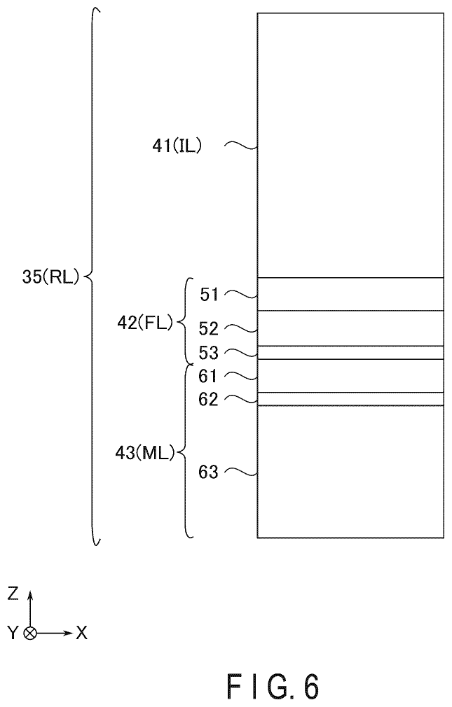

FIG. 6 is a cross-sectional view illustrating an example of a cross-sectional structure of a reference layer included in the magnetoresistance element according to the embodiment. As illustrated in FIG. 6, the ferromagnet 35 includes an interface layer (IL) 41, a function layer (FL) 42, and a main layer (ML) 43. The main layer 43, the function layer 42, and the interface layer 41 are stacked in this order from the word line WL side toward the bit line BL side between the upper surface of the nonmagnet 36 and the lower surface of the nonmagnet 34.

The interface layer 41 includes a ferromagnet forming magnetic tunnel coupling together with the nonmagnet 34 and the ferromagnet 33. The ferromagnet included in the interface layer 41 contains, for example, iron (Fe), and further contains at least one element selected from cobalt (Co) and nickel (Ni). In addition, the ferromagnet included in the interface layer 41 may further contain boron (B). More specifically, for example, the ferromagnet included in the interface layer 41 contains iron cobalt boron (FeCoB) or iron boride (FeB). The ferromagnet included in the interface layer 41 may have a body-centered cubic crystal structure.

The function layer 42 has a function of suppressing degradation of magnetic characteristics caused by a difference in crystal structure between the interface layer 41 and the main layer 43. The function layer 42 includes, for example, a nonmagnet 51, a ferromagnet 52, and a nonmagnet 53. The nonmagnet 53, the ferromagnet 52, and the nonmagnet 51 are stacked in this order from the word line WL side toward the bit line BL side between the upper surface of the main layer 43 and the lower surface of the interface layer 41. The nonmagnet 51 contains, for example, molybdenum (Mo). The ferromagnet 52 contains, for example, cobalt (Co). The nonmagnet 53 contains, for example, molybdenum (Mo).

The main layer 43 has a function of increasing the anisotropic magnetic field of the reference layer RL. The main layer 43 has a crystal structure different from that of the interface layer 41. The main layer 43 includes, for example, a ferromagnet 61, a nonmagnet 62, and a ferromagnet 63. The ferromagnet 63, the nonmagnet 62, and the ferromagnet 61 are stacked in this order from the word line WL side toward the bit line BL side between the upper surface of the nonmagnet 36 and the lower surface of the function layer 42.

The ferromagnet 61 contains, for example, cobalt (Co). In one example, the ferromagnet 61 has a film thickness that may be designed to be 0.1 nm.

The nonmagnet 62 contains, for example, platinum (Pt). The nonmagnet 62 preferably has a film thickness of less than or equal to 0.5 nm. From the viewpoint of improving the strength of antiferromagnetic coupling between the reference layer RL and a shift cancelling layer SCL (described later) while reducing the diameter of the magnetoresistance element MTJ, the film thickness of the nonmagnet 62 is more preferably greater than or equal to 0.01 nm and less than or equal to 0.3 nm. In one example, the film thickness of the nonmagnet 62 may be designed to be 0.04 nm.

The ferromagnet 63 contains, for example, cobalt (Co). The ferromagnet 63 preferably has a film thickness of greater than or equal to 0.25 nm. In one example, the film thickness of the ferromagnet 63 may be designed to be 0.4 nm.

The configuration of the magnetoresistance element MTJ will be described again with reference to FIG. 5.

The nonmagnet 36 is a nonmagnetic conductor used as a spacer layer (SP). The nonmagnet 36 contains at least one element selected from, for example, ruthenium (Ru), osmium (Os), iridium (Ir), vanadium (V), and chromium (Cr). The nonmagnet 36 is in contact with, for example, the ferromagnet 63.

The ferromagnet 37 is used as the shift cancelling layer SCL. The ferromagnet 37 has an axis of easy magnetization in a direction perpendicular to the film surface of the ferromagnet 37. The magnetization direction of the ferromagnet 37 may be toward either the bit line BL side or the word line WL side along the Z axis. The magnetization direction of the ferromagnet 37 is fixed similarly to the ferromagnet 35 and oriented toward the ferromagnet 35 in the example illustrated in FIG. 5. The ferromagnet 37 contains, for example, at least one alloy selected from cobalt platinum (CoPt), cobalt nickel (CoNi), and cobalt palladium (CoPd). Similarly to the ferromagnet 35, the ferromagnet 37 may be a layer stack including a plurality of layers. In this case, the ferromagnet 37 may include, for example, at least one multilayer film selected from a multilayer film (Co/Pt multilayer film) of cobalt (Co) and platinum (Pt), a multilayer film (Co/Ni multilayer film) of cobalt (Co) and nickel (Ni), and a multilayer film (Co/Pd multilayer film) of cobalt (Co) and palladium (Pd).

The ferromagnets 35 and 37 are antiferromagnetically coupled by the nonmagnet 36. That is, the ferromagnets 35 and 37 are coupled so as to have magnetization directions antiparallel to each other. Therefore, in the example illustrated in FIG. 5, the magnetization directions of the ferromagnets 35 and 37 are opposite to each other. The coupling structure of the ferromagnet 35, the nonmagnet 36, and the ferromagnet 37 is referred to as a synthetic anti-ferromagnetic structure. As a result, the ferromagnet 37 can offset the effect of a stray field of the ferromagnet 35 on the magnetization direction of the ferromagnet 33. Therefore, the hysteresis of the ferromagnet 33 is prevented from being shifted by the stray field of the ferromagnet 35 or the like.

The nonmagnet 38 is a nonmagnetic conductor used as an under layer (UL). The nonmagnet 38 has a function as an electrode that improves electrical connectivity to the bit line BL and the word line WL. In addition, the nonmagnet 38 contains, for example, a high melting point metal. The high melting point metal refers to, for example, a material having a melting point higher than those of iron (Fe) and cobalt (Co), and contains, for example, at least one element selected from zirconium (Zr), hafnium (Hf), tungsten (W), chromium (Cr), molybdenum (Mo), niobium (Nb), titanium (Ti), tantalum (Ta), vanadium (V), ruthenium (Ru), and platinum (Pt).

In the embodiment, a spin injection write system is adopted in which the magnetization direction of the storage layer SL is controlled by directly applying a spin torque into the storage layer SL by the write current. The magnetoresistance element MTJ can take either the low resistance state or the high resistance state based on whether the relative relationship between the magnetization directions of the storage layer SL and the reference layer RL is parallel or antiparallel.

When a write current Ic0 of a certain magnitude is applied to the magnetoresistance element MTJ in the direction of an arrow A1 in FIG. 5, that is, in the direction from the storage layer SL toward the reference layer RL, the relative relationship between the magnetization directions of the storage layer SL and the reference layer RL becomes parallel. In this parallel state, the resistance value of the magnetoresistance element MTJ is lowest, and the magnetoresistance element MTJ is set to the low resistance state. This low resistance state is referred to as a “parallel (P) state” and is defined by, for example, data “0”.

In addition, when a write current Ic1 greater than the write current Ic0 is applied to the magnetoresistance element MTJ in the direction of an arrow A2 in FIG. 5, that is, in the direction from the reference layer RL toward the storage layer SL (the direction opposite to the arrow A1), the relative relationship between the magnetization directions of the storage layer SL and the reference layer RL becomes antiparallel. In the antiparallel state, the resistance value of the magnetoresistance element MTJ is highest, and the magnetoresistance element MTJ is set to the high resistance state. This high resistance state is referred to as an “antiparallel (AP) state” and is defined by, for example, data “1”.

In the following description, description will be made according to the data defining method described above, but the method of defining using the data “1” and the data “0 ” is not limited to the example described above. For example, the P state may be defined by the data “1”, and the AP state may be defined by the data “0”.

### 1.2. Effects According to Embodiment

According to the embodiment, the main layer 43 in the reference layer RL includes the nonmagnet 62 containing platinum (Pt) and the ferromagnet 63 disposed on the spacer layer SP side of the nonmagnet 62 and containing cobalt (Co). As a result, the main layer 43 can generate perpendicular magnetic anisotropy at an interface between the nonmagnet 62 and the ferromagnet 63. As a result, the energy (Jex) of the antiferromagnetic coupling between the reference layer RL and the shift cancelling layer SCL and the anisotropy energy (Ku) of the reference layer RL can be improved. Therefore, it is possible to suppress an increase in the amount of current for reversing the magnetization direction of the storage layer SL due to the spin torque injected into the reference layer RL. Therefore, the write characteristics of the magnetoresistance element MTJ can be improved.

Note that the diameter of the magnetoresistance element MTJ tends to be decreased as the integration density is increased. As the diameter of the magnetoresistance element MTJ is decreased, the film thickness of the magnetoresistance element MTJ also needs to be decreased. However, since the decrease in size leads to an increase in a shift of the hysteresis of the storage layer SL, the thickness of the shift cancelling layer SCL may be increased. Therefore, particularly in a case where the diameter of the magnetoresistance element MTJ is less than or equal to 25 nm, it may be difficult for a multilayer of platinum (Pt) and cobalt (Co) to be disposed in the reference layer RL in order to maximize the perpendicular magnetic anisotropy to be generated, from the viewpoint of avoiding an increase in the thickness of the magnetoresistance element MTJ.

According to the embodiment, the nonmagnet 62 of the main layer 43 has a film thickness of less than or equal to 0.3 nm. As a result, even in a case where the diameter of the magnetoresistance element MTJ is less than or equal to 25 nm, it is possible to generate magnetic anisotropy of a significant magnitude while suppressing an increase in the thickness of the magnetoresistance element MTJ.

In addition, the ferromagnet 63 of the main layer 43 has a film thickness of greater than or equal to 0.25 nm. This makes it possible to suppress diffusion of platinum (Pt) contained in the nonmagnet 62 into an interface between the ferromagnet 63 and the spacer layer SP in annealing treatment performed after stacking of the various films. Therefore, it is possible to suppress weakening of the antiferromagnetic coupling between the reference layer RL and the shift cancelling layer SCL.

Furthermore, the main layer 43 in the reference layer RL is disposed between the nonmagnet 53 in the function layer 42 and the nonmagnet 62 in the main layer 43, and further includes the ferromagnet 61 containing cobalt (Co). Thus, the nonmagnet 62 can also generate perpendicular magnetic anisotropy at an interface with the ferromagnet 61. Therefore, the magnetic characteristics of the magnetoresistance element MTJ can be further improved.

### 2. Modifications and the Like

Various modifications can be applied to the above-described embodiment. Configurations different from those described in the embodiment will be mainly described. Description of configurations equivalent to those described in the embodiment will be omitted as appropriate.

### 2.1. First Modification

In the above-described embodiment, the case where the ferromagnet 61 is disposed between the nonmagnet 62 of the main layer 43 and the nonmagnet 53 of the function layer 42 has been described, but the present disclosure is not limited thereto. For example, a nonmagnet corresponding to the nonmagnet 62 may be disposed so as to be in contact with the nonmagnet 53.

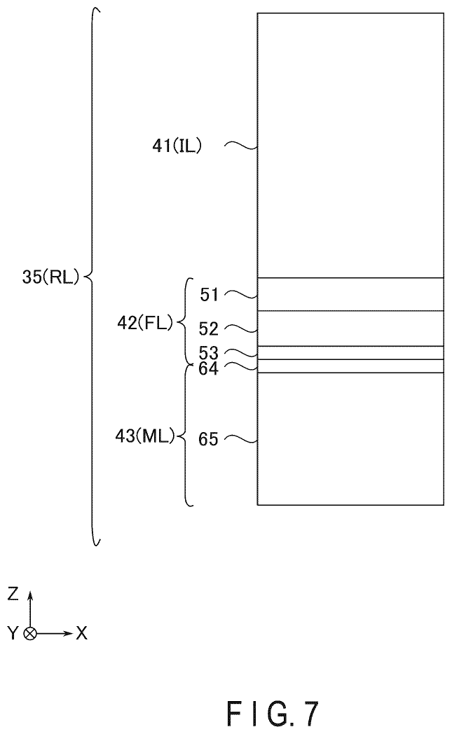

FIG. 7 is a cross-sectional view illustrating an example of a reference layer included in a magnetoresistance element according to a first modification. FIG. 7 corresponds to FIG. 6 in the embodiment. As illustrated in FIG. 7, a main layer 43 includes a nonmagnet 64 and a ferromagnet 65. The ferromagnet 65 and the nonmagnet 64 are stacked in this order from the word line WL side toward the bit line BL side between the upper surface of the nonmagnet 36 and the lower surface of the function layer 42.

The nonmagnet 64 is disposed so as to be in contact with the nonmagnet 53 of the function layer 42. The nonmagnet 64 contains, for example, platinum (Pt). The nonmagnet 64 preferably has a film thickness of less than or equal to 0.5 nm. From the viewpoint of improving the strength of antiferromagnetic coupling between the reference layer RL and the shift cancelling layer SCL while reducing the diameter of the magnetoresistance element MTJ, the film thickness of the nonmagnet 64 is more preferably greater than or equal to 0.01 nm and less than or equal to 0.3 nm. In one example, the film thickness of the nonmagnet 64 may be designed to be 0.04 nm.

The ferromagnet 65 contains, for example, cobalt (Co). The ferromagnet 65 preferably has a film thickness of greater than or equal to 0.25 nm. In one example, the film thickness of the ferromagnet 65 may be designed to be 0.5 nm.

Also in the above-described configuration, the main layer 43 can generate perpendicular magnetic anisotropy at an interface between the nonmagnet 64 and the ferromagnet 65. As a result, the energy of the antiferromagnetic coupling between the reference layer RL and the shift cancelling layer SCL and the anisotropy energy of the reference layer RL can be improved. Therefore, as in the embodiment, the write characteristics of the magnetoresistance element MTJ can be improved.

### 2.2. Second Modification

In the above-described embodiment, the case where the function layer 42 has the stacked structure of the nonmagnets and the ferromagnet has been described, but the present disclosure is not limited thereto. For example, the function layer 42 may have a single layer structure of a nonmagnet.

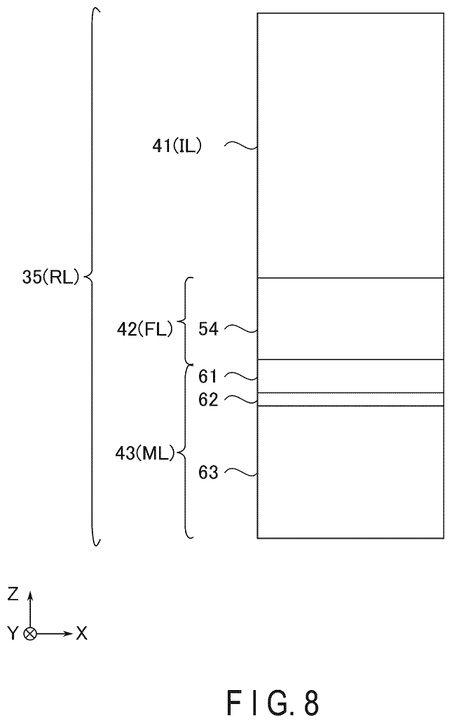

FIG. 8 is a cross-sectional view illustrating an example of a reference layer included in a magnetoresistance element according to a second modification. FIG. 8 corresponds to FIG. 6 in the embodiment. As illustrated in FIG. 8, a function layer 42 has a single-layer structure including a nonmagnet 54.

The nonmagnet 54 is disposed so as to be in contact with each of the interface layer 41 and the ferromagnet 61 of the main layer 43. The nonmagnet 54 contains, for example, molybdenum (Mo). Note that the nonmagnet 54 is not limited to a single-layer structure of molybdenum (Mo), and may have a single-layer structure of tungsten (W) or a single-layer structure of tantalum (Ta).

Also in the above-described configuration, the function layer 42 can suppress degradation of magnetic characteristics caused by a difference in crystal structure between the interface layer 41 and the main layer 43. Therefore, as in the embodiment, the write characteristics of the magnetoresistance element MTJ can be improved.

### 2.3. Third Modification

In addition, a case where the nonmagnet 64 described above in the first modification is in direct contact with the function layer 42 and a case where the function layer 42 described above in the second modification has the single layer structure of the nonmagnet may be combined.

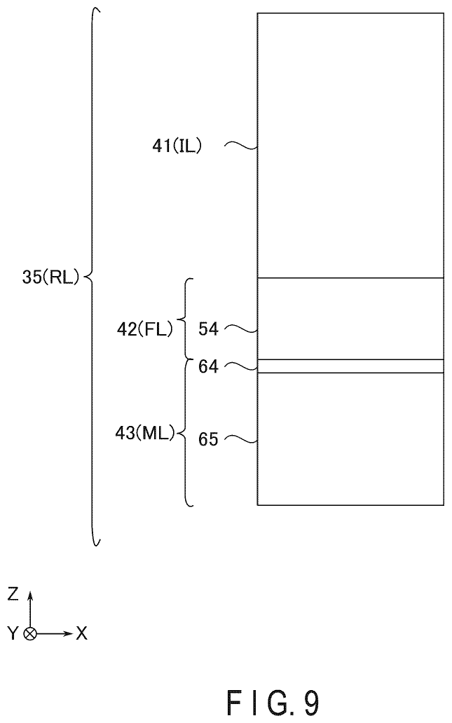

FIG. 9 is a cross-sectional view illustrating an example of a reference layer included in a magnetoresistance element according to a third modification. FIG. 9 corresponds to FIG. 6 in the embodiment. As illustrated in FIG. 9, a main layer 43 includes a nonmagnet 64 and a ferromagnet 65. The ferromagnet 65 and the nonmagnet 64 are stacked in this order from the word line WL side toward the bit line BL side between the upper surface of the nonmagnet 36 and the lower surface of the function layer 42. The function layer 42 has the single-layer structure including the nonmagnet 54.

As described above, also in the configuration in which the configuration described in the first modification and the configuration described in the second modification are combined, the main layer 43 can generate perpendicular magnetic anisotropy at an interface between the nonmagnet 64 and the ferromagnet 65. In addition, the function layer 42 can suppress degradation of the magnetic characteristics caused by a difference in crystal structure between the interface layer 41 and the main layer 43. Therefore, as in the embodiment, the write characteristics of the magnetoresistance element MTJ can be improved.

### 2.4. Fourth Modification

In addition, in the above-described embodiment, the first modification, the second modification, and the third modification, the case where the magnetoresistance element MTJ has a top free structure (in other words, a bottom SAF structure in which the shift cancelling layer SCL is located below the reference layer RL) in which the storage layer SL is located above the reference layer RL has been described, but the present disclosure is not limited thereto. For example, the magnetoresistance element MTJ may have a bottom-free structure (in other words, a top SAF structure in which the shift cancelling layer SCL is located above the reference layer RL) in which the storage layer SL is located below the reference layer RL.

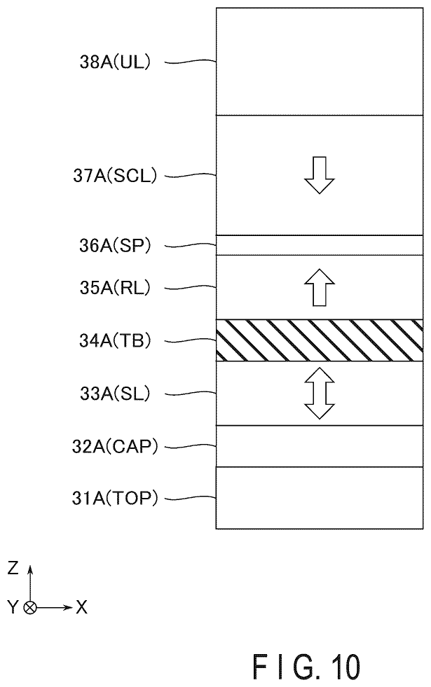

FIG. 10 is a cross-sectional view illustrating an example of a cross-sectional structure of a magnetoresistance element according to a fourth modification. FIG. 10 corresponds to FIG. 5 in the embodiment.

As illustrated in FIG. 10, the magnetoresistance element MTJ includes a nonmagnet 31A, a nonmagnet 32A, a ferromagnet 33A, a nonmagnet 34A, a ferromagnet 35A, a nonmagnet 36A, a ferromagnet 37A, and a nonmagnet 38A stacked in this order from the substrate 20 side. The nonmagnet 31A, the nonmagnet 32A, the ferromagnet 33A, the nonmagnet 34A, the ferromagnet 35A, the nonmagnet 36A, the ferromagnet 37A, and the nonmagnet 38A are made of materials equivalent to those of the nonmagnet 31, the nonmagnet 32, the ferromagnet 33, the nonmagnet 34, the ferromagnet 35, the nonmagnet 36, the ferromagnet 37, and the nonmagnet 38, respectively, and have functions equivalent to those of the nonmagnet 31, the nonmagnet 32, the ferromagnet 33, the nonmagnet 34, the ferromagnet 35, the nonmagnet 36, the ferromagnet 37, and the nonmagnet 38, respectively.

Even in the bottom-free structure as described above, since the configuration of the reference layer RL is equivalent to that in the embodiment except that the upper limit is inverted, effects equivalent to those in the embodiment can be obtained.

While certain embodiments have been described, these embodiments have been presented by way of example only, and are not intended to limit the scope of the invention. Indeed, the embodiments described herein may be embodied in a variety of other forms; furthermore, various omissions, substitutions and changes in the form of the embodiments described herein may be made without departing from the spirit of the inventions. The embodiments and modifications are included in the scope and spirit of the invention and are included in the scope of the claimed inventions and their equivalents.

What is claimed is:

1. A magnetic memory device comprising
a magnetoresistance element including:
a first ferromagnetic layer;
a second ferromagnetic layer;
a third ferromagnetic layer;
a first nonmagnetic layer disposed between the first ferromagnetic layer and the second ferromagnetic layer; and
a second nonmagnetic layer disposed between the second ferromagnetic layer and the third ferromagnetic layer, wherein
the second ferromagnetic layer includes
a third nonmagnetic layer containing platinum (Pt),
a fourth ferromagnetic layer containing cobalt (Co), and disposed on a side of the second nonmagnetic layer with respect to the third nonmagnetic layer, and
the third nonmagnetic layer has a film thickness of less than or equal to 0.3 nm.

2. The magnetic memory device according to claim 1, wherein
the fourth ferromagnetic layer has a film thickness of greater than or equal to 0.25 nm.

3. The magnetic memory device according to claim 1, wherein
the magnetoresistance element has a diameter of less than or equal to 25 nm.

4. The magnetic memory device according to claim 1, wherein
the second ferromagnetic layer further includes
a fourth nonmagnetic layer containing at least one element selected from molybdenum (Mo), tungsten (W), and tantalum (Ta), and disposed on a side of the first nonmagnetic layer with respect to the third nonmagnetic layer, and
a fifth ferromagnetic layer containing at least one element selected from iron (Fe), cobalt (Co), and nickel (Ni), and disposed on a side of the first nonmagnetic layer with respect to the fourth nonmagnetic layer.

5. The magnetic memory device according to claim 4, wherein
the second ferromagnetic layer further includes a sixth ferromagnetic layer containing cobalt (Co), and disposed between the fourth nonmagnetic layer and the fourth ferromagnetic layer.

6. The magnetic memory device according to claim 4, wherein
the fourth nonmagnetic layer is in contact with the fourth ferromagnetic layer.

7. The magnetic memory device according to claim 1, wherein
the first nonmagnetic layer contains magnesium oxide (MgO).

8. The magnetic memory device according to claim 1, wherein
the second nonmagnetic layer contains at least one element selected from ruthenium (Ru), osmium (Os), rhodium (Rh), iridium (Ir), vanadium (V), and chromium (Cr).

9. The magnetic memory device according to claim 8, wherein
the second ferromagnetic layer and the third ferromagnetic layer are antiferromagnetically coupled via the second nonmagnetic layer.

10. A magnetic memory device comprising
a magnetoresistance element including:
a first ferromagnetic layer;
a second ferromagnetic layer;
a third ferromagnetic layer;
a first nonmagnetic layer disposed between the first ferromagnetic layer and the second ferromagnetic layer; and
a second nonmagnetic layer disposed between the second ferromagnetic layer and the third ferromagnetic layer, wherein
the second ferromagnetic layer includes
a third nonmagnetic layer containing platinum (Pt),
a fourth ferromagnetic layer containing cobalt (Co), and disposed on a side of the second nonmagnetic layer with respect to the third nonmagnetic layer,
a fourth nonmagnetic layer containing at least one element selected from molybdenum (Mo), tungsten (W), and tantalum (Ta), and disposed on a side of the first nonmagnetic layer with respect to the third nonmagnetic layer, and
a fifth ferromagnetic layer containing at least one element selected from iron (Fe), cobalt (Co), and nickel (Ni), and disposed on a side of the first nonmagnetic layer with respect to the fourth nonmagnetic layer, and
the fourth nonmagnetic layer is in contact with the fourth ferromagnetic layer.

11. The magnetic memory device according to claim 10, wherein the third nonmagnetic layer has a film thickness of less than or equal to 0.3 nm.

12. The magnetic memory device according to claim 10, wherein
the fourth ferromagnetic layer has a film thickness of greater than or equal to 0.25 nm.

13. The magnetic memory device according to claim 10, wherein
the magnetoresistance element has a diameter of less than or equal to 25 nm.

14. The magnetic memory device according to claim 10, wherein the first nonmagnetic layer contains magnesium oxide (MgO).

15. The magnetic memory device according to claim 10, wherein
the second nonmagnetic layer contains at least one element selected from ruthenium (Ru), osmium (Os), rhodium (Rh), iridium (Ir), vanadium (V), and chromium (Cr).

16. The magnetic memory device according to claim 15, wherein
the second ferromagnetic layer and the third ferromagnetic layer are antiferromagnetically coupled via the second nonmagnetic layer.
